(19) United States
(12) Patent Application Publication
(10) Pub. No.: US 2003/0031951 A1
(43) Pub. Date: Feb. 13, 2003

(54) Photosensitive composition, photosensitive lithographic printing plate, and process for producing lithographic printing plate

(76) Inventor: Maru Aburano, Oura-gun (JP)

Correspondence Address: BAKER & BOTTS, 30 ROCKEFELLER PLAZA, NEW YORK, NY, 10112

(21) Appl. No.: 10/140,836

(22) Filed: May 7, 2002

(30) Foreign Application Priority Data
May 10, 2001 (JP) P2001-140038

(51) Int. Cl. G03F 7/039; G03F 7/26

(52) U.S. Cl. 430/270.1; 430/302; 430/944; 430/905; 430/964

(57) ABSTRACT

A photosensitive composition can be directly written on by a solid laser or semiconductor laser emitting infrared rays and is superior in storage stability and baking scum resistance, a photosensitive lithographic printing plate, and a process for producing a lithographic printing plate are provided. The photosensitive composition contains an alkali-soluble resin, an infrared absorber which absorbs light to generate heat, and an antioxidant which prevents the alkali-soluble resin and the infrared absorber from oxidizing. The antioxidant is preferably a phosphite compound and/or a mercaptoimidazole compound. Preferably, the photosensitive composition further contains a cyclic acid anhydride. In a photosensitive lithographic printing plate, a photosensitive layer made of the photosensitive composition described above is formed on a substrate. According to the process for producing a lithographic printing plate, the photosensitive layer of the photosensitive lithographic printing plate described above is imagewise exposed to activating rays having a wavelength of 700 nm or more, and then the exposed area is removed by dissolving in an alkali developing solution.

### BACKGROUND OF THE INVENTION

1. Field of the Invention

The present invention relates to a photosensitive composition, which is suited to be directly written on by a laser and is superior in storage stability, a photosensitive lithographic printing plate, and a process for producing a lithographic printing plate.

2. Description of Related Art

Recently, remarkable advances have been made in lasers, and, particularly, high-output and small lasers have been developed and are readily available as solid lasers and semiconductor lasers, which emit infrared rays having a wavelength within a range from 760 to 1200 nm. These lasers are very useful as a recording light source in the case of directly making a printing plate using digital data from a computer or the like.

As a conventional photosensitive composition capable of recording by an infrared laser, for example, there may be mentioned those comprising an alkali-soluble resin, which has a phenolic hydroxyl group and is soluble in an alkali compound, such as novolak resin, and an infrared absorber which absorbs light to generate heat. In this photosensitive composition, the exposed area generates heat by the infrared absorber when exposed to infrared light, and therefore the alkali solubility of the photosensitive composition is enhanced, thus making it possible to develop using a solution of an alkali compound. Such a photosensitive composition is a positive-working photosensitive composition.

Japanese Patent Application, First Publication No. 11-119419 discloses a positive-working photosensitive composition containing a cyclic acid anhydride. Also, Japanese Patent Application, First Publication No. 2000-177261 discloses a lithographic printing original plate having a photosensitive layer obtained by applying a positive-working photosensitive composition containing a cyclic acid anhydride of the following chemical formula (1) on a substrate. Since this cyclic acid anhydride has a bond which conjugates with carbonyl groups of a carboxylic anhydride, the stability of the carbonyl groups is improved. Therefore, the decomposition rate during the storage as time elapses is reduced and the cyclic acid anhydride is gradually decomposed at a proper rate to generate an acid. Consequently, the developability is always maintained at a fixed level in the photosensitive layer, thus making it possible to maintain the solubility in an alkali developing solution.

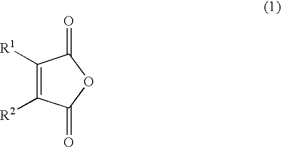

In the formula, R¹ and R² each independently represents a hydrogen atom, or an optionally substituted C₁₋₁₂ alkyl, alkenyl, alkoxy, cycloalkyl, aryl, carbonyl, carboxy or carboxylate ester group. R¹ and R² may be combined together to form a ring structure.

Also, Japanese Patent Application, First Publication No. 2000-066394 discloses a material for a positive-working lithographic printing plate containing a phenolic compound of the following chemical formula (2). The phenolic compound is dispersed in an alkali-soluble resin and strongly interacts with dissociative hydrogen in the alkali-soluble resin, thereby improving the film density. Therefore, the film quality in the coating film exhibits an enhanced resistance to external factors such as water and heat and the storage stability at high temperature and high humidity is improved.

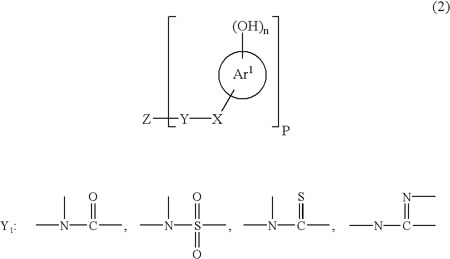

In the formula, Ar¹ represents an optionally substituted aromatic hydrocarbon ring; n represents an integer of 1 to 3 and P represents an integer of 1 to 4; X represents a divalent linking group; Y represents a divalent to tetravalent linking group having at least one partial structure selected from the group Y₁, or a terminal group whose terminal is a hydrogen atom; and Z is absent when Y is a terminal group, and represents a linking group having a valence of P, or a terminal group when Y is a linking group.

Japanese Patent Application, First Publication No. 2000-3031 discloses a photosensitive composition containing at least one solvent selected from ketones of the following chemical formula (3) and glycol ethers of the following chemical formula (4). It is described that the solvent, infrared absorber and alkali-soluble resin are contained in a certain fixed ratio by containing such a solvent and, therefore, storage stability is improved.

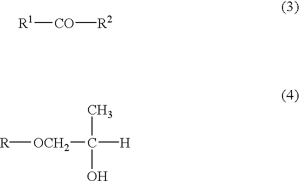

In the chemical formula (3), R¹ and R² represent a hydrogen atom or a hydrocarbon group, and the hydrocarbon group has 4 or more carbon atoms in total. R¹ and R² are not combined to form a ring. R in the chemical formula (4) is a hydrocarbon group having 3 or more carbon atoms.

Japanese Patent Application, First Publication No. 11-291652 discloses a positive-working image forming material containing an oxidizing agent having a reduction potential of −1.2 V (based on a standard calomel electrode). It is described that this image forming material has satisfactory storage stability.

However, in Japanese Patent Application, First Publication No. 11-119419 and Japanese Patent Application, First Publication No. 2000-177261, since the storage stability is improved by a cyclic acid anhydride, the storage stability in an atmosphere wherein water exists was merely improved.

In Japanese Patent Application, First Publication No. 2000-066394, although an influence of external factors is hardly exerted because the film of the material for lithographic printing plate has high density, an influence of internal factors such as natural deterioration of the resin is exerted.

In Japanese Patent Application, First Publication No. 2000-3031, a specific solvent does not positively improve the storage stability.

In Japanese Patent Application, First Publication No. 11-291652, the oxidizing agent does not positively improve the storage stability, but does not lower the storage stability.

Therefore, the photosensitive composition described above had a problem in that the developability is lowered when stored for a long period, particularly under conditions of high temperature and high humidity, because of its unsatisfactory storage stability.

A conventional photosensitive composition is sometimes heat-treated in a baking oven to improve the printing durability after the completion of the development. There was a problem in that scum is liable to occur in the non-image area in this baking treatment. However, a means for solving the problems is not described in any of the above patent publications.

### BRIEF SUMMARY OF THE INVENTION

Under these circumstances, the present invention has been made, and an object thereof is to provide a photosensitive composition which can directly write, based on digital data of a computer, using a solid laser or a semiconductor laser, which emits infrared light, and is superior in storage stability and baking scum resistance, a photosensitive lithographic printing plate, and a process for producing a lithographic printing plate.

The photosensitive composition of the present invention comprises an alkali-soluble resin, an infrared absorber, and an antioxidant.

In the photosensitive composition of the present invention, the antioxidant is preferably a phosphite compound.

In the photosensitive composition of the present invention, the antioxidant is preferably a mercaptoimidazole compound.

Preferably, the photosensitive composition of the present invention further comprises a cyclic acid anhydride.

In the photosensitive lithographic printing plate of the present invention, a photosensitive layer made of the photosensitive composition described above is formed on a substrate.

The process for producing a lithographic printing plate of the present invention is characterized by imagewise exposing the photosensitive layer of a photosensitive lithographic printing plate described above to activating rays having a wavelength of 700 nm or more and dissolving the exposed area in an alkali developer to remove the exposed area.

The photosensitive composition described above contains the alkali-soluble resin, the infrared absorber, and the antioxidant, and are therefore superior in storage stability and baking scum resistance.

The photosensitive composition of the present invention is more superior in storage stability and baking scum resistance when the antioxidant is a phosphite compound.

The photosensitive composition of the present invention is more superior in storage stability and baking scum resistance when the antioxidant is a mercaptoimidazole compound.

The photosensitive composition of the present invention is superior in storage stability even in an atmosphere wherein moisture exists when it further contains a cyclic acid anhydride.

In the photosensitive lithographic printing plate of the present invention, a photosensitive layer made of the photosensitive composition described above is formed on a substrate. Therefore, a photosensitive lithographic printing plate having excellent storage stability and baking scum resistance is provided.

According to the process for producing a lithographic printing plate of the present invention, a photosensitive layer made of the photosensitive composition described above is formed on a substrate. Therefore, a photosensitive lithographic printing plate having excellent storage stability and baking scum resistance can be produced.

### DETAILED DESCRIPTION OF THE INVENTION

The present invention will be described below.

The alkali-soluble resin in the present invention is a resin which is soluble in a solution of an alkali compound. Examples of the alkali-soluble resin include novolak resin, polyvinyl phenolic resin, and copolymer having an alkali-soluble group such as carboxyl group, phenolic hydroxyl group, sulfonic acid group, sulfonamide group, or active imino group. Among these resins, a novolak resin or a polyvinyl phenolic resin is preferred.

Examples of the novolak resin include those obtained by polycondensing at least one kind of aromatic hydrocarbon such as phenol, m-cresol, o-cresol, p-cresol, 2,5-xylenol, 3,5-xylenol, resorcin, pyrogallol, bisphenol, bisphenol A, trisphenol, o-ethylphenol, m-ethylphenol, p-ethylphenol, propyl phenol, n-buylphenol, t-butylphenol, t-butylphenol, 1-naphthol and 2-naphthol with at least one kind of aldehyde or ketone selected from aldehydes such as formaldehyde, acetaldehyde, propionaldehyde, benzaldehyde and furfural, and ketones such as acetone, methyl ethyl ketone and methyl isobutyl ketone in the presence of an acidic catalyst.

Paraformaldehyde and paraaldehyde may be respectively used in place of formaldehyde and acetaldehyde.

Aromatic hydrocarbons of the novolak resin are more preferably novolak resins obtained by polycondensing at least one kind of phenol selected from phenol, m-cresol, o-cresol, p-cresol, 2,5-xylenol, 3,5-xylenol and resorcin with at least one kind of aldehyde selected from formaldehyde, acetaldehyde and propionaldehyde.

Among these novolak resins, novolak resins as polycondensates of phenols and aldehydes in a mixing molar ratio of m-cresol:p-cresol:2,5-xylenol:3,5-xylenol:resorcin=40-100:0-50:0-20:0-20:0-20 are preferred. Alternatively, novolak resins as polycondensates of phenols and aldehydes in a mixing molar ratio of phenol:m-cresol:p-cresol=70-100:0-30:0-20 are preferred. Alternatively, novolak resins as polycondensates of phenols and aldehydes in a mixing molar ratio of phenol:m-cresol:p-cresol=10-100:0-60:0-40 are preferred.

The weight-average molecular weight (relative to polystyrene standards) as measured by gel permeation chromatography of the novolak resin is preferably within a range from 500 to 30,000. When the weight-average molecular weight is less than 500, the developer resistance of the non-exposed area is sometimes lowered. On the other hand, when the weight-average molecular weight exceeds 30000, the developability of the exposed area is sometimes lowered.

Examples of the polyvinyl phenolic resin include one or two or more kinds of hydroxystyrenes. Examples of hydroxystyrenes include o-hydroxystyrene, m-hydroxystyrene, p-hydroxystyrene, 2-(o-hydroxyphenyl)propylene, 2-(m-hydroxyphenyl)propylene and 2-(p-hydroxyphenyl)propylene.

The hydroxystyrenes may have a halogen such as chlorine, bromine, iodine or fluorine, or a C₁-C₄ alkyl substituent in the aromatic ring.

The polyvinyl phenolic resin is usually synthesized by radical polymerization or cationic polymerization of one or two or more kinds of hydroxystyrenes. Such a polyvinyl phenolic resin may be partially hydrogenated. It may also be a resin wherein OH groups of polyvinyl phenols are protected with a t-butoxycarbonyl group, a pyranyl group or a furanyl group.

Among the polyvinyl phenolic resin, a polyvinyl phenol resin is preferred. Although the aromatic ring of polyvinyl phenol may have a C₁-C₄ alkyl substituent, a polyvinyl phenol having no substituent is particularly preferred.

The weight-average molecular weight of the polyvinyl phenol resin is preferably within a range from 1,000 to 100,000. When the weight-average molecular weight is less than 1,000, a satisfactory coating film sometimes cannot be formed. On the other hand, when the weight-average molecular weight exceeds 100,000, the solubility of the exposed area to the alkali developer tends to be lowered, thus making it impossible to obtain a pattern.

The infrared absorber has a light absorption range in an infrared range of a wavelength of 700 nm or more, and preferably from 750 to 1200 nm, and absorbs light having a wavelength within this range, thereby generating heat. Specifically, there can be used various pigments which absorb light having a wavelength within this range to generate heat. Examples thereof include cyanine pigments, squalirium pigments, polymethine pigments, dithiobenzyl-nickel complexes and pyrylium pigment.

Among these cyanine pigments, an indol cyanine (indocyanine) or thiazole cyanine (thiocyanine) pigment is particularly preferred.

The content of these infrared absorbers is preferably within a range from 0.01 to 50% by weight, and more preferably from 0.1 to 20% by weight. When the content is less than 0.01% by weight, the sensitivity to infrared rays is lowered. On the other hand, when the content exceeds 50% by weight, the film formability becomes poor and the wear durability is lowered.

These infrared absorbers generally have an action of substantially lowering the solubility of the photosensitive composition containing an alkali-soluble resin in the aqueous alkali solution, and also have the resistance of the non-exposed area to the alkali developing solution.

It is also possible to use other compounds having an action of substantially lowering the solubility of the photosensitive composition containing an alkali-soluble resin in the aqueous alkali solution in combination.

Examples of such a compound include onium salt, aromatic sulfone compound, aromatic sulfone ester compound, phosphate ester compound, aromatic carboxylate ester compound, aromatic disulfone compound, aromatic ketone compound, aromatic aldehyde compound, aromatic ether compound and o-quinonediazide compound.

The antioxidant is not specifically limited as long as it prevents oxidation of the alkali-soluble resin and infrared absorber, and examples thereof include phosphorus-based antioxidants, sulfur-based antioxidants, amine-based antioxidants and phenol-based antioxidants.

Among these phosphorus-based antioxidants, a phosphite compound is particularly preferred. As used herein, the phosphite refers to a compound wherein hydrogens of phosphorous acid are substituted with hydrocarbon groups. Examples of such a phosphite compound include triphenyl phosphite, diphenylisodecyl phosphite, phenylisodecyl phosphite, triethyl phosphite, tri-n-propyl phosphite and trimethyl phosphite.

The content of the phosphite compound is preferably within a range from 0.5 to 20% by weight, and more preferably from 1 to 10% by weight. When the content is less than 0.5% by weight, the storage stability is sometimes not improved. On the other hand, when the content exceeds 20% by weight, the developability of the exposed area (non-image area) is lowered because the dissolution inhibition effect on the developer is too great.

Among the sulfur-based antioxidants, a mercaptoimidazole compound is preferred. As used herein, the mercaptoimidazole compound refers to a compound represented by the following chemical formula (5), wherein hydrogen attached to carbon at the 2-position of imidazole is substituted with a mercapto group. Also hydrogens attached to carbons at the 4- and 5-positions of mercaptoimidazole may be substituted with hydrocarbon groups.

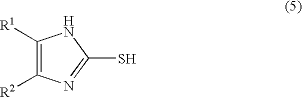

In the chemical formula (5), R¹ and R² represent a hydrogen atom or a hydrocarbon group. R¹ and R² may be combined to form a ring.

Examples of such a mercaptoimidazole compound include 2-mercaptobenzimidazole and 2-mercaptomethylbenzimidazole.

The content of the mercaptoimidazole compound is preferably within a range from 0.5 to 20% by weight, and more preferably from 1 to 10% by weight. When the content is less than 0.5% by weight, the storage stability is sometimes not improved. On the other hand, when the content exceeds 20% by weight, the developer resistance of the non-exposed area (image area) is lowered because the dissolution inhibition effect on the developer is too great.

Among the amine-based antioxidants, a hindered amine-based compound is preferred. As such a hindered amine-based compound, there can be used SANOL LS-770, SANOL LS-765, SANOL LS-622LD and Chimasorb 944 (manufactured by Sankyo Co., Ltd.); CYASORB UV-3346 (manufactured by Sun Chemical Company Ltd.); NOCRAC 224, NOCRAC CD and Uvasil 299-299LM (manufactured by Ohuchishinko Chemical Industrial Co. Ltd.); MARK LA-63 and MARK RKLA-68 (manufactured by Asahi Denka Kogyo K.K.); TINUVIN 144, TINUVIN 123 and TINUVIN 312 (manufactured by Ciba Specialty Chemical Co.); and oligomer type and polymer type compounds having a hindered amine structure.

The content of the hindered amine-based compound is preferably within a range from 0.5 to 20% by weight. When the content is less than 0.5% by weight, the storage stability is sometimes not improved. On the other hand, when the content exceeds 20% by weight, the developer resistance of the exposed area (non-image area) is lowered because the dissolution inhibition effect on the developer is too great.

Among the phenol-based antioxidant, a hindered phenol-based compound is preferred. Examples of the hindered phenol-based compound include Yoshinox BHT (2,6-di-t-butyl-4-methylphenol), Tominox TT (tetrakis-[methylene-3-(3,5′-di-t-butyl-4′-hydroxyphenyl) propionate]methane), Yoshinox SR, Yoshinox BB, Yoshinox 2246G, Yoshinox 425, Yoshinox 250, Yoshinox 930, Tominox SS, Tominox 917 and GSY-314 (manufactured by Yoshitomi Fine Chemicals, Ltd.,); IRGANOX245 (manufactured by Ciba Specialty Chemical Co.); and 2,6-butyl-4-nonylphenol.

The content of the hindered phenol-based compound is preferably within a range from 0.5 to 20% by weight. When the content is less than 0.5% by weight, the storage stability is sometimes not improved. On the other hand, when the content exceeds 20% by weight, the developer resistance of the exposed area (non-image area) is lowered because the dissolution inhibition effect to the developer is too great.

The photosensitive composition of the present invention preferably contains a cyclic acid anhydride. Examples of such a cyclic acid anhydride include phthalic anhydride, 3,4,5,6-tetrahydrophthalic anhydride, tetrachlorophthalic anhydride, 3-hydroxyphthalic anhydride, 3-methylphthalic anhydride, 3-phenylphthalic anhydride, trimellitic anhydride, pyromellitic anhydride, maleic anhydride, phenylmaleic anhydride, dimethylmaleic anhydride and dichloromaleic anhydride.

Among these cyclic acid anhydrides, a compound having two or more acid anhydrides per molecule, for example, pyromellitic dianhydride, biphenyltetracarboxylic dianhydride or benzophenonetetracarboxylic dianhydride, is preferred. A polymer compound such as styrene-maleic anhydride copolymer or ethylene-maleic anhydride copolymer is also preferred.

The content of the cyclic acid anhydride is preferably within a range from 0.5 to 20% by weight, and more preferably from 1 to 10 by weight. When the content is less than 0.5% by weight, the storage stability is sometimes not improved. On the other hand, when the content exceeds 20% by weight, the developer resistance of the non-exposure area (image area) is lowered because the dissolution inhibition effect on the developer is too poor.

The photosensitive composition of the present invention may contain a compound capable of crosslinking by an acid and a compound capable of generating an acid by heat. In this case, since the exposure area is crosslinked by exposure to light, the alkali-soluble resin of the non-exposure area is dissolved in a developer and the photosensitive composition becomes negative.

If necessary, the photosensitive composition of the present invention may contain additives having a specific function. Examples of the additive include dyes, pigments, surfactants, developing modifiers, adhesion modifiers and sensitivity modifiers.

The photosensitive composition containing the components described above is generally used after dissolving in a solvent. The solvent is not specifically limited as long as it sufficiently dissolves the components described above and can form a satisfactory coating film. Examples of such a solvent include cellosolve-based solvents, propylene glycol-based solvents, ester-based solvents, alcohol-based solvents, ketone-based solvents, and high polar solvents such as dimethylformamide, dimethylacetamide or N-methyl pyrrolidone.

The amount of the solvent is preferably 2 to 30 times as much as the total amount of the photosensitive composition. When the amount is less than 2 times, the photosensitive composition is sometimes not sufficiently dissolved. On the other hand, when the amount exceeds 30 times, the drying property becomes poor and a satisfactory coating film sometimes cannot be obtained.

Since the photosensitive composition contains the alkali-soluble resin, the infrared absorber and the antioxidant, the storage stability of the photosensitive composition can be improved by preventing oxidation of the alkali-soluble resin and the infrared absorber. The antioxidant prevents oxidation deterioration of the alkali-soluble resin and the infrared absorber when heat-treated after the development, and therefore scum does not occur in the non-image area and the baking scum resistance is excellent.

In the photosensitive composition of the present invention, the antioxidant is a phosphite compound. Consequently, a higher effect of preventing oxidation of the alkali-soluble resin and the infrared absorber is exerted, and therefore the storage stability and the baking scum resistance of the photosensitive composition are further improved.

In the photosensitive composition of the present invention, the antioxidant is a mercaptoimidazole compound. Consequently, a higher effect of preventing oxidizing the alkali-soluble resin and the infrared absorber is exerted, and therefore the storage stability and the baking scum resistance of the photosensitive composition are further improved.

The photosensitive composition of the present invention further comprises a cyclic acid anhydride. Consequently, water reacts with an acid anhydride to generate carboxylic acid in an atmosphere wherein water exists. Since this carboxylic acid improves the alkali solubility, the storage stability is further improved when an alkali compound exists in the atmosphere.

The lithographic printing plate of the present invention will be described below. This lithographic printing plate comprises a substrate and a photosensitive layer made of the photosensitive composition described above formed on the substrate.

The substrate is not specifically limited as long as the photosensitive composition can be applied thereon and, for example, a paper, a paper laminated with a resin, a metal plate, or a plastic film can be used.

Examples of the metal sheet include sheets made of aluminum, zinc, or copper.

Examples of the plastic film include films made of cellulose diacetate, cellulose triacetate, cellulose propionate, cellulose butyrate, cellulose butyrate acetate, cellulose nitrate, polyethylene terephthalate, polyethylene, polystyrene, polypropylene, polycarbonate, or polyvinyl acetal.

The substrates used in the present invention are preferably aluminum sheets which are subjected to surface treatments such as graining treatment, anodizing treatment and, if necessary, sealing treatment.

Examples of the method of graining treatment include mechanical methods and electrolytic etching methods. Examples of the mechanical methods include ball polishing methods, brush polishing methods, liquid honing polishing methods, and buffing methods. The electrolytic etching method is conducted by using a bath containing inorganic acids such as phosphoric acid, sulfuric acid, hydrochloric acid and nitric acid alone or a mixture of two or more kinds thereof. After the graining treatment, a desmutting treatment is optionally conducted by using an aqueous solution of an alkali or acid, followed by neutralization and further washing with water.

The anodizing treatment is conducted by electrolysis using a solution containing sulfuric acid, chromic acid, oxalic acid, phosphoric acid and malonic acid alone or in combination as an electrolytic solution and using an aluminum sheet as an anode.

Examples of the sealing treatment include boiling water treatment, steam treatment, sodium silicate treatment, and aqueous dichromate salt solution treatment.

The method of forming a photosensitive layer made of a photosensitive composition on a substrate is generally a method of applying the photosensitive composition on the substrate, but is not limited as long as the photosensitive composition can formed the photosensitive layer.

Examples of the method of applying the photosensitive composition on the substrate include rotary coating, wire bar coating, dip coating, air knife coating, roll coating, blade coating and curtain coating methods.

In such a photosensitive lithographic printing plate, the photosensitive layer is preferably imagewise exposed to activating rays having a wavelength of 700 nm or more. More preferably, the photosensitive layer is imagewise exposed to infrared rays having a wavelength within a range from 760 nm to 1200 nm. Examples of the light source include semiconductor laser, He—Ne laser, YAG laser and carbon dioxide laser.

As the alkali developer for developing after exposure, an aqueous alkali solution is preferably used. Examples of the alkali compound used in the aqueous alkali solution include alkali metal salt such as sodium hydroxide, potassium hydroxide, sodium carbonate, potassium carbonate, sodium metasilicate, potassium metasilicate, sodium secondary phosphate, or sodium tertiary phosphate.

If necessary, anionic surfactants, amphoteric surfactants, and organic solvents such as alcohol can be added to the developing solution.

The developed lithographic printing plate is post-treated with washing water, rinsing liquid containing a surfactant, or a desensitizing solution containing gum arabic and a starch derivative. In the posttreatment, these treatments can be used in combination.

The lithographic printing plate thus produced is sometimes used after subjecting to a baking treatment to improve the printing durability.

In the photosensitive lithographic printing plate described above, the photosensitive layer made of the photosensitive composition is formed on the substrate and this photosensitive composition contains an antioxidant and is superior in storage stability and baking scum resistance. Consequently, the photosensitive lithographic printing plate is also superior in storage stability and baking scum resistance.

### EXAMPLES

The present invention will be described in more detail by way of examples, but the present invention is not limited by these examples.

First, an aluminum sheet having a thickness of 0.24 mm was degreased with aqueous sodium hydroxide and then electrolytically polished in a 20% hydrochloric acid bath to obtain a grained sheet having a center line average roughness (Ra) of 0.5 m. The resulting grained sheet was anodized in a 20% sulfuric acid bath at a current density of 2 A/dm² to form an oxide film of 2.7 g/m², which was washed with water and then dried to obtain an aluminum substrate.

Then, a photosensitive composition was prepared. As components of the photosensitive composition, an alkali-soluble resin such as m, p-cresol novolak (m/p=6/4, weight-average molecular weight=5000) was used and an infrared absorber such as cyanine dye A of the chemical formula (6) or cyanine dye B of the chemical formula (7) was used as the infrared absorber. As the antioxidant, a 2-mercaptobenzimidazole mercaptoimidazole compound such as 2-methylthiobenzimidazole, a phosphite compound such as triphenyl phosphite or triethyl phosphite, and a hindered amine-based compound such as T UVIN 144 were used. 1-methoxy-2-propanol and methanol were used as the solvent, pyromellitic dianhyride was used as the cyclic acid anhydride, and crystal violet was used as the pigment.

On the aluminum substrate described above, the photosensitive composition prepared according to the formulation shown in Table 1 was applied using a roll coater and dried at 100° C. for 2 minutes to form a photosensitive layer, thereby obtaining a lithographic printing plate. The weight of the dry coating film was 2.0 g/m².

TABLE 1

| Components of photosensitive | | | | | | | Comparative | |
|---|---|---|---|---|---|---|---|---|
| composition | Examples | | | | | | Examples | |
| (unit: g) | 1 | 2 | 3 | 4 | 5 | 6 | 1 | 2 |
| m, p-cresol novolak | 9.1 | 9.1 | 9.1 | 9.1 | 9.1 | 9.1 | 9.6 | 9.1 |
| (m/p = 6/4, Mw = 5000) | | | | | | | | |
| Crystal violet | 0.2 | 0.2 | 0.2 | 0.2 | 0.2 | 0.2 | 0.2 | 0.2 |
| Cyanine dye A | 0.1 | 0.1 | 0.1 | 0.1 | 0.1 | 0.1 | 0.1 | 0.1 |
| Cyanine dye B | 0.1 | 0.1 | 0.1 | 0.1 | 0.1 | 0.1 | 0.1 | 0.1 |
| 1-methoxy-2-propanol | 60.0 | 60.0 | 60.0 | 60.0 | 60.0 | 60.0 | 60.0 | 60.0 |
| Methanol | 30.0 | 30.0 | 30.0 | 30.0 | 30.0 | 30.0 | 30.0 | 30.0 |
| 2-methylthiobenzimidazole | 0.5 | — | — | — | — | — | — | — |
| 2-mercaptobenzimidazole | — | 0.5 | — | — | — | — | — | — |
| Triphenyl phosphite | — | — | 0.5 | 0.25 | — | — | — | — |
| Pyromellitic anhydride | — | — | — | 0.25 | — | — | — | 0.5 |
| Triethyl phosphite | — | — | — | — | 0.5 | — | — | — |
| TINUVIN 144 | — | — | — | — | — | 0.5 | — | — |

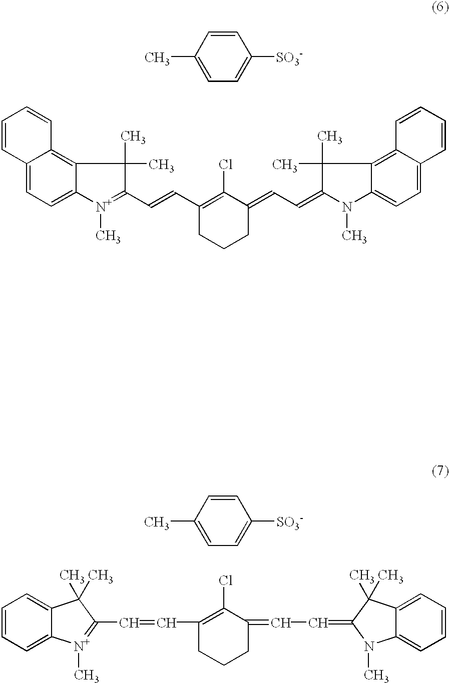

The resulting lithographic printing plate was stored at normal temperature for 3 days after production, exposed to light (laser power: 10 W, rotational speed: 140 rpm) using an exposure device (Trendsetter, manufactured by Creo Co.) and then developed at 30° C. for 25 seconds, using an automatic developing machine (PK-910, manufactured by Kodak Polychrome Graphics Japan Ltd.) and a developer (PD1, dilution ratio of 1:7, manufactured by Kodak Polychrome Graphics Japan Ltd.). The image formability of the lithographic printing plate after the development was visually evaluated. The evaluation results are shown in Table 2.

TABLE 2

| | 3 Days | After an accelerated | |
|---|---|---|---|
| | after coating | aging treatment | Baking scum |
| Example 1 | image was formed | image was formed | did not occur |
| Example 2 | image was formed | image was formed | did not occur |
| Example 3 | image was formed | image was formed | did not occur |
| Example 4 | image was formed | image was formed | did not occur |
| Example 5 | image was formed | image was formed | did not occur |
| Example 6 | image was formed | image was formed | did not occur |
| Comparative | image was formed | poor development | occurred |
| Example 1 | | | |
| Comparative | image was formed | image was formed | occurred |
| Example 2 | | | |

To evaluate the baking scum resistance of the lithographic printing plate, a baking surface conditioning liquid (UT-2, manufactured by Kodak Polychrome Graphics Japan Ltd.) was applied after the development, and then a baking treatment was conducted in a baking oven (SPBO-I, manufactured by Koyo Chemical Co.) at 250° C. for 5 minutes. After washing with water, applying a gum solution (PF-2, dilution ratio of 1:1, manufactured by Kodak Polychrome Graphics Japan Ltd.), inking with printing ink (Naturalis, manufactured by DAINIPPON INK & CHEMICALS Co., Ltd.) and washing with water, the scum resistance of the non-image area was visually evaluated. The evaluation results are shown in Table 2.

To evaluate the long-term storage stability, the lithographic printing plate produced in the same manner was stored in a packaged state in an atmosphere at 40° C. and 80% RH for 48 hours, exposed to light (laser power: 10 W, rotational speed: 140 rpm) using an exposure device (Trendsetter, manufactured by Creo Co.) and then developed at 30° C. for 25 seconds, using an automatic developing machine (PK-910, manufactured by Kodak Polychrome Graphics Japan Ltd.) and a developer (PD1, dilution ratio of 1:7, manufactured by Kodak Polychrome Graphics Japan Ltd.). The image formability of the lithographic printing plate after an accelerated aging treatment was visually evaluated. The evaluation results are shown in Table 2.

In all lithographic printing plates stored at normal temperature of Examples 1 to 6 and Comparative Examples 1 and 2, an image could be formed. After an accelerated aging treatment, the lithographic printing plates of Examples 1 to 6, which uses a photosensitive composition containing an antioxidant, and the lithographic printing plate of Comparative Example 2, which uses a photosensitive composition containing no antioxidant, were superior in image formability. In particular, the lithographic printing plate of Example 4 was superior in image formability.

On the other hand, the lithographic printing plates of Comparative Example 1, which uses a photosensitive composition containing no antioxidant, was inferior in developability after an accelerated aging treatment and the solubility of the exposure area was poor, resulting in poor development wherein a film residue remained.

With respect to the scum resistance after baking, the lithographic printing plates of Examples 1 to 6 were satisfactory because scum of the non-image area did not occur in inking after the baking treatment. On the other hand, in the lithographic printing plates of Comparative Examples 1 and 2, ink was adhered to the non-image area and scum occurred in the inking after the baking treatment.

What is claimed is:

1. A photosensitive composition comprising an alkali-soluble resin, an infrared absorber and an antioxidant.

2. The photosensitive composition according to claim 1, wherein the antioxidant is selected from the group consisting of phosphorus-based antioxidants, sulfur-based antioxidants, amine-based antioxidants and phenol-based antioxidants.

3. The photosensitive composition according to claim 2, wherein the antioxidant is a phosphite compound.

4. The photosensitive composition according to claim 3, wherein the phosphite compound is selected from the group consisting of triphenyl phosphite, diphenylisodecyl phosphite, phenylisodecyl phosphite, triethyl phosphite, tri-n-propyl phosphite and trimethyl phosphite.

5. The photosensitive composition according to claim 3, wherein the content of the phosphite compound is within a range from 0.5 to 20% by weight.

6. The photosensitive composition according to claim 1, wherein the antioxidant is a mercaptoimidazole compound.

7. The photosensitive composition according to claim 6, wherein the content of the mercaptoimidazole compound is within a range from 0.5 to 20% by weight.

8. The photosensitive composition according to claim 1, further comprising a cyclic acid anhydride.

9. The photosensitive composition according to claim 8, wherein the cyclic acid anhydride is selected from the group consisting of phthalic anhydride, 3,4,5,6-tetrahydrophthalic anhydride, tetrachlorophthalic anhydride, 3-hydroxyphthalic anhydride, 3-methylphthalic anhydride, 3-phenylphthalic anhydride, trimellitic anhydride, pyromellitic anhydride, maleic anhydride, phenylmaleic anhydride, dimethylmaleic anhydride and dichloromaleic anhydride.

10. The photosensitive composition according to claim 1, wherein the alkali-soluble resin is selected from the group consisting of novolak resin, polyvinyl phenolic resin, and copolymer having an alkali-soluble group.

11. The photosensitive composition according to claim 1, wherein the infrared absorber is selected from the group consisting of cyanine pigments, squalirium pigments, polymethine pigments, dithiobenzyl-nickel complexes and pyrylium pigment.

12. A photosensitive lithographic printing plate comprising a substrate and a photosensitive layer made of the photosensitive composition of claim 1 formed on the substrate.

13. A process for producing a lithographic printing plate, which comprises imagewise exposing a photosensitive layer of the photosensitive lithographic printing plate of claim 12 to activating rays having a wavelength of 700 nm or more and dissolving the exposed area in an alkali developer to remove the exposed area.
